(19) United States
(12) Patent Application Publication
(10) Pub. No.: US 2007/0070748 A1
(43) Pub. Date: Mar. 29, 2007

(54) Method for Discharging and Equalizing Sense Lines to Accelerate Correct MRAM Operation

(75) Inventors: Kuang-Lun Chen, St. Paul, MN (US); James Chyi Lai, St. Paul, MN (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: NORTHERN LIGHTS SEMICONDUCTOR CORP., St. Paul, MN (US)

(21) Appl. No.: 11/530,602

(22) Filed: Sep. 11, 2006

Related U.S. Application Data
(60) Provisional application No. 60/716,259, filed on Sep. 12, 2005.

(51) Int. Cl. G11C 11/00

(52) U.S. Cl. 365/203; 365/208; 365/158

(57) ABSTRACT

A method and apparatus for discharging and equalizing sense lines embedded in a magnetoresistive random access memory integrated circuit (MRAM IC) includes using a current source connected to a current source node. A sense line is connected to the current source node. A bit decode element is coupled to turn on and allow the current source to source a current through the sense line so as to set the current source node to a selected voltage. A discharger is connected at a first terminal to the current source node so as to accelerate discharge of the current source node when the current source turns off.

### CROSS-REFERENCE TO RELATED APPLICATION

This application claims the priority benefit of U.S. Provisional Application Ser. No. 60/716,259, filed Sep. 12, 2005, the full disclosures of which are incorporated herein by reference

### BACKGROUND

1. Field of Invention

The present invention relates to magnetoresistive random access memory integrated circuits (MRAM IC's), and, more particularly, to a method and apparatus for discharging and equalizing sense lines to ensure and accelerate read and write operation cycles in an MRAM IC.

2. Description of Related Art

Magnetoresistive Random Access Memory (MRAM) is typically designed to write or read eight bits (one byte) in one complete timing cycle. For example, the eight bits share the same word line, but each bit resides on its own sense line. To ensure the ability of writing “1” and “0” into different bits in one byte, the word line current must turn on for write “1” and for write “0” in one complete cycle. It follows that each write “1” or write “0” duration is called a half cycle. In normal operation, the sense line current turns on when the word line current is in the half cycle of intended written information.

A drawback of conventional MRAM IC's is that a time gap is needed to separate write “1” and write “0” word line currents in order to ensure correct operation. The purpose for the time gap is to allow sense current to drop to a safe level before write “0” word line current turns on. As a result, there exists a need, addressed by the present invention, for an accelerated discharging process that permits a shorter read/write cycle and, consequently, faster operation of MRAM.

### SUMMARY

According to one embodiment of the present invention, an apparatus for discharging and equalizing sense lines embedded in a magnetoresistive random access memory integrated circuit (MRAM IC) is provided. The apparatus includes a current source connected to a current source node. A sense line is connected to the current source node. A bit decode element is coupled to turn on and allow the current source to source a current through the sense line so as to set the current source node to a selected voltage. A discharger is connected at a first terminal to the current source node so as to accelerate discharge of the current source node when the current source turns off.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1A graphically represents waveforms for sense current lines and word current lines during an MRAM write “1” cycle.

FIG. 1B graphically represents waveforms for sense current lines and word current lines during an MRAM write “0” cycle.

FIG. 2 is a schematic circuit diagram of an example of an apparatus for discharging and equalizing sense lines embedded in a magnetoresistive random access memory integrated circuit (MRAM IC) according to one embodiment of the present invention using an n-channel CMOS transistor.

FIG. 3 is a schematic circuit diagram of an example of a sense line having a discharger embedded in an MRAM IC according to another embodiment of the present invention using a p-channel CMOS transistor.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

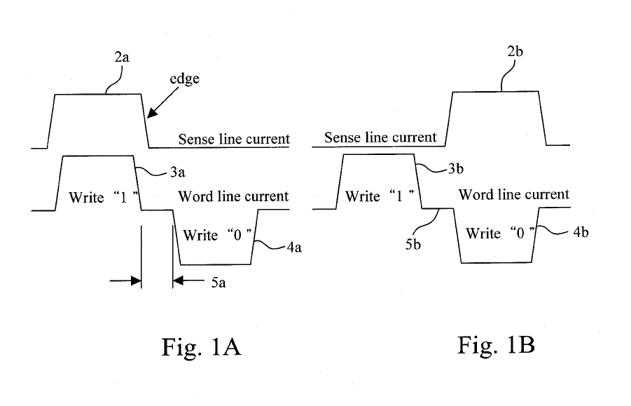

Referring now to FIG. 1A there shown graphically are waveforms representing sense current lines and word current lines during an MRAM write “1” cycle. A first portion of sense line current waveform 2a is a high signal during a word line current write “1” half cycle 3a shown on the left of the word line current waveform. A second portion of sense line current waveform 2a goes low during a word line current write “0” half cycle 4a shown on the right of the word line current waveform. A time gap 5a provides a transition level between the write “1” half cycle and the write “0” half cycle.

Referring now to FIG. 1B there shown graphically are waveforms representing sense current lines and word current lines during an MRAM write “0” cycle. A first portion of sense line current waveform 2b is a low signal during a word line current write “1” half cycle 3b shown on the left of the word line current waveform. A second portion of sense line current waveform 2b rises to a higher level during a word line current write “0” half cycle 4b shown on the right of the word line current waveform. A time gap 5b provides a transition level between the write “1” half cycle and the write “0” half cycle.

It will be understood by those skilled in the art having read this disclosure that alternate logic circuitry may be employed wherein the first half cycle is defined to write “0” and the second half cycle is defined to write “1”. It will be understood by those skilled in the art having read this disclosure that other equivalent write “1” and/or write “0” waveforms will be understood to be within the scope of this invention.

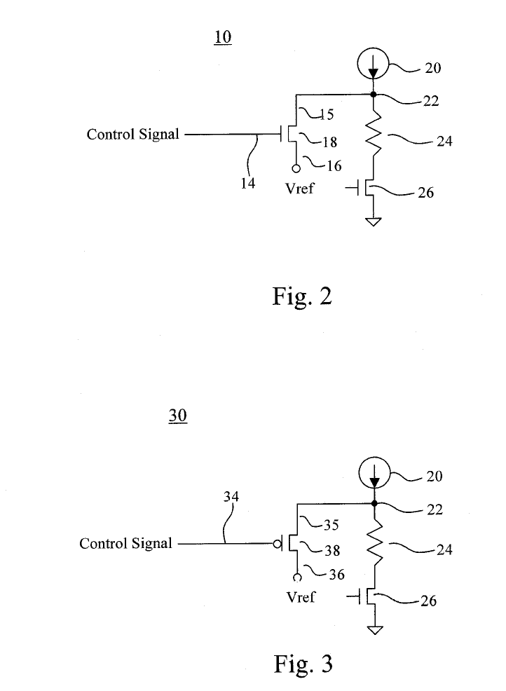

Referring now to FIG. 2 there shown is a schematic circuit diagram of an example of an apparatus for discharging and equalizing sense lines embedded in a magnetoresistive random access memory integrated circuit (MRAM IC) according to one embodiment of the present invention using an n-channel CMOS transistor. The apparatus for discharging and equalizing sense lines embedded in an MRAM IC 10 includes a current source 20 connected to a current source node 22, a sense line 24 connected to the current source node 22, a bit decode element 26 is coupled to turn on and allow the current source to source a current through the sense line 24 so as to set the current source node 22 to a selected voltage, and a discharger 18 is connected at a first terminal 14 to the current source node 22 so as to accelerate discharge of the current source node 22 when the current source 20 turns off. The discharger 18 has the first terminal 14, a second terminal 15 and a third terminal 16. The first terminal 14 is connected to a control signal 12 that operates to turn the discharger 18 on and off as needed. The second terminal 15 is coupled to the current source node 22 and the third terminal 16 connects to a reference voltage (Vref. In one embodiment of the invention, the discharger 18 comprises an n-channel CMOS transistor.

In another embodiment of the invention, the discharger 18 may be connected to short the current source node to a reference voltage when turned on so as to operate as an equalizer. This is advantageous over known devices because MRAM magnetic memory cells are often constructed from giant magnetoresistance (GMR) devices. Typically, signal strength in a GMR is about 3 mV, which is minute compared to signal strength in other types of memories. It is very difficult to sense such a small signal, particularly in the presence of an offset voltage between a signal line and a reference line. One way to eliminate the offset voltage between the signal line and reference line is to equalize the signal line and reference line to the same voltage using the discharger 18, for example.

To promote further understanding of the present invention, it is helpful to contrast it with a case where the discharger is removed. If the discharger were not present during the write cycle, for example, the bit decode transistor would turn on and allow the current source to source a current through the sense line thereby setting current source node 22 to a particular voltage. In the case of a missing discharger, when the current source turns off as indicated by edge 1 in FIG. 1A, the voltage at current source node 22 must be discharged through the bit decode transistor 26 before the write “0” word line current turns on. Discharging the voltage at current source node 22 takes time, necessitating a longer time gap between write “1” and write “0” half cycles. Thus, the presence of the discharger as contemplated by the present invention accelerates discharging the voltage at current source node 22. As a result the whole cycle time can be significantly shortened.

Referring now to FIG. 3 there shown schematically is an example of a schematic circuit diagram of a sense line having a discharger embedded in an MRAM IC 30 as contemplated by an alternate embodiment of the present invention using a p-channel CMOS transistor 38. The p-channel CMOS transistor 38 has a first terminal 34, a second terminal 35 and a third terminal 36. The first terminal 34 is connected to a control signal 32 that operates to turn the p-channel CMOS transistor 38 on and off as needed. The other elements are arranged substantially similarly as those described with respect to FIG. 2. Operation of the p-channel CMOS transistor 38 is substantially similar to that of an n-channel CMOS transistor, although the control signal must be appropriately modified to control a p-channel device as will be appreciated by those skilled in the art having read this disclosure.

Having explained examples of apparatus for carrying out the embodiments of the invention, a method for discharging and equalizing sense lines in a MRAM IC will now be described. One example of a method contemplated by the present invention comprises the steps of using a current source for sourcing current to a current source node, connecting a sense line to the current source node, controlling a bit decode element to turn on and allow the current source to source a current through the sense line so as to set the current source node to a selected voltage, and using a discharger to discharge the current source node so as to accelerate discharge of the current source node when the current source turns off. The method may be carried out by the apparatus as described hereinabove, or by equivalent apparatus.

The invention has been described herein in considerable detail in order to comply with the Patent Statutes and to provide those skilled in the art with the information needed to apply the novel principles of the present invention, and to construct and use such exemplary and specialized components as are required. However, it is to be understood that the invention may be carried out by specifically different equipment and devices, and that various modifications, both as to the equipment details and operating procedures, may be accomplished without departing from the true spirit and scope of the present invention.

What is claimed is:

1. An apparatus for discharging and equalizing sense lines embedded in a magnetoresistive random access memory integrated circuit (MRAM IC) comprising:
a current source connected to a current source node;
a sense line connected to the current source node;
a bit decode element coupled to turn on and allow the current source to source a current through the sense line thereby setting the current source node to a selected voltage; and
a discharger connected at a first terminal to the current source node so as to accelerate discharge of the current source node when the current source turns off.

2. The apparatus for discharging and equalizing sense lines of claim 1, wherein the discharger comprises an n-channel complementary metal oxide semiconductor (CMOS) transistor.

3. The apparatus for discharging and equalizing sense lines of claim 1, wherein the discharger comprises a p-channel CMOS transistor.

4. The apparatus for discharging and equalizing sense lines of claim 1, wherein the discharger is connected to short the current source node to a reference voltage when turned on so as to operate as an equalizer.

5. The apparatus for discharging and equalizing sense lines of claim 4, wherein the MRAM IC comprises giant magnetoresistance material.

6. A method for discharging and equalizing sense lines in a magnetoresistive random access memory integrated circuit (MRAM IC) comprising the steps of:
using a current source for sourcing current to a current source node;
connecting a sense line to the current source node;
controlling a bit decode element to turn on and allow the current source to source a current through the sense line so as to set the current source node to a selected voltage; and
using a discharger to discharge the current source node so as to accelerate discharge of the current source node when the current source turns off.

7. The method for discharging and equalizing sense lines of claim 6, wherein the discharger comprises an n-channel complementary metal oxide semiconductor (CMOS) transistor.

8. The method for discharging and equalizing sense lines of claim 6, wherein the discharger comprises a p-channel CMOS transistor.

9. The method for discharging and equalizing sense lines of claim 6 wherein the discharger is connected to short the current source node to a reference voltage when turned on so as to operate as an equalizer.

10. The method for discharging and equalizing sense lines of claim 9 wherein the MRAM IC comprises giant magnetoresistance material.

11. An apparatus for discharging and equalizing sense lines embedded in a magnetoresistive random access memory integrated circuit (MRAM IC) comprising:
a current source connected to a current source node;
a sense line connected to the current source node;
a bit decode element coupled to turn on and allow the current source to source a current through the sense line so as to set the current source node to a selected voltage; and
a complementary metal oxide semiconductor (CMOS) transistor connected at a first terminal to the current source node so as to accelerate discharge of the current source node when the current source turns off.

12. The apparatus for discharging and equalizing sense lines of claim 11, wherein the CMOS transistor comprises an n-channel CMOS transistor.

13. The apparatus for discharging and equalizing sense lines of claim 11, wherein the CMOS transistor comprises a p-channel CMOS transistor.

14. The apparatus for discharging and equalizing sense lines of claim 11, wherein the CMOS transistor is connected to short the current source node to a reference voltage when turned on so as to operate as an equalizer.

15. The apparatus for discharging and equalizing sense lines of claim 14 wherein the MRAM IC comprises giant magnetoresistance material.
